(19) United States
(12) Patent Application Publication
(10) Pub. No.: US 2025/0105063 A1
(43) Pub. Date: Mar. 27, 2025

(54) MANUFACTURING METHOD AND TEST METHOD OF POWER MODULE

(71) Applicants: Hyundai Motor Company, Seoul (KR); Kia Corporation, Seoul (KR)

(72) Inventors: Tae Woo KWANG, Hanam-si (KR); Young Jin SON, Suwon-si (KR)

(21) Appl. No.: 18/432,506

(22) Filed: Feb. 5, 2024

(30) Foreign Application Priority Data
Sep. 21, 2023 (KR) 10-2023-0126140

(51) Int. Cl. H01L 21/66; G01R 1/067; H01L 23/498

(52) U.S. Cl. CPC H01L 22/14; G01R 1/06711; H01L 23/49811

(57) ABSTRACT

A manufacturing method of a power module includes operations of bonding a semiconductor device to a lower substrate, disposing an upper bonding member on an upper portion of the semiconductor device; contacting a probe device with the upper bonding member, electrically connecting the probe device to a tester and testing electrical characteristics of the semiconductor device, and bonding an upper substrate to the semiconductor device through the upper bonding member.

### CROSS-REFERENCE TO RELATED APPLICATION(S)

This application claims benefit of priority to Korean Patent Application No. 10-2023-0126140, filed on Sep. 21, 2023, in the Korean Intellectual Property Office, the disclosure of which is incorporated herein by reference in its entirety.

### TECHNICAL FIELD

The present disclosure relates to a manufacturing method and a test method of a power module, and specifically to a manufacturing method and a test method that can test electrical characteristics of a power module before it is completed.

### BACKGROUND

A power module is a device used to convert direct current (DC) power into alternating current (AC) power when driving motors of hybrid vehicles, electric vehicles, or the like. Typically, the power module may include a substrate, a power semiconductor device, a switching device bonded to the substrate, a power lead for applying power to the power semiconductor device, a signal lead providing a control signal to the power semiconductor device, and the like.

After the power module described above is manufactured, the power module is selected as a good or defective product through electrical characteristics inspection. The electrical characteristics inspection performed on the power module may generally be performed in an End-Of-Line (EOL) evaluation process, and may include a direct current (DC) test, an alternating current (AC) test, and a withstand voltage test.

In some cases, as the electrical characteristics of power modules in a form of a finished product with complete packaging, are tested, since defects in a semiconductor device cannot be detected in advance and even in the case of a semiconductor device with problems, all subsequent processes are performed, there is a problem of unnecessary consumption of materials and significant process loss.

### SUMMARY

An aspect of the present disclosure is to provide a manufacturing method that can test electrical characteristics by contacting an inspection device with a solder member disposed on a semiconductor device to detect defects in the semiconductor device in an intermediate process before the power module is completed.

According to an aspect of the present disclosure, a manufacturing method of a power module may include operations of: bonding a semiconductor device to a lower substrate; disposing an upper bonding member on an upper portion of the semiconductor device; contacting a probe device with the upper bonding member; electrically connecting the probe device to a tester and testing electrical characteristics of the semiconductor device; and bonding an upper substrate to the semiconductor device through the upper bonding member.

In some implementations, the manufacturing method may further include a molding operation performed after the operation of bonding the upper substrate.

In some implementations, the manufacturing method may further include an operation of wire bonding a signal lead and the semiconductor device, wherein the wire bonding may be performed between the operation of testing electrical characteristics of the semiconductor device and the operation of bonding the upper substrate.

In some implementations, the semiconductor device may be bonded to the lower substrate through a lower bonding member disposed between a lower surface of the semiconductor device and the lower substrate.

In some implementations, the lower bonding member and the upper bonding member may include a material having electrical conductivity.

In some implementations, the lower bonding member and the upper bonding member may include a material capable of at least one of soldering and sintering.

In some implementations, the probe device may include a contact pin electrically connected to the tester and provided to contact the upper bonding member, wherein the contact pin may be configured to be electrically connected to the semiconductor device through the upper bonding member.

In some implementations, the probe device may further include a plate to which the contact pin is detachably coupled, and the semiconductor device and the contact pins may be provided in plural.

In some implementations, the operation of contacting the probe device with the upper bonding member may include an operation of adjusting the number and position of the plurality of contact pins coupled to the plate corresponding to the number and position of the plurality of semiconductor devices.

In some implementations, the operation of disposing an upper bonding member on an upper portion of the semiconductor device may include an operation of disposing a first upper bonding member on an upper surface of the semiconductor device, and the probe device may be configured to contact the first upper bonding member.

In some implementations, the operation of disposing an upper bonding member on an upper portion of the semiconductor device may include operations of disposing a first upper bonding member on an upper surface of the semiconductor device, disposing a spacer on an upper portion of the first upper bonding member, and disposing a second upper bonding member on an upper portion of the spacer, and the probe device may be configured to contact the second upper bonding member.

In some implementations, the probe device may be configured to be electrically connected to the semiconductor device through the second upper bonding member, the spacer, and the first upper bonding member.

In some implementations, in testing the electrical characteristics of the semiconductor device, the tester may apply an electrical signal to the semiconductor device through the probe device.

According to another aspect of the present disclosure, a test method of a power module may include operations of: preparing a power module, a device under test for testing electrical characteristics; contacting a probe device with the power module, the device under test; and electrically connecting the probe device to a tester and applying an electrical signal to the power module, the device under test, wherein the operation of preparing the power module, the device under test may include an operation of manufacturing a power module work in process in which a semiconductor device is bonded to a lower substrate and a bonding member is disposed on an upper portion of the semiconductor device, wherein the probe device may contact the bonding member disposed on the upper portion of the semiconductor device.

In some implementations, the probe device may include a contact pin provided in an amount corresponding to that of the semiconductor device, and may be configured so that the contact pin contacts the bonding member in the operation of contacting the probe device with the power module, the device under test.

In some implementations, the bonding member may include a material having electrical conductivity.

In some implementations, a finished product of the power module may be a structure in which the semiconductor device is disposed and bonded between the upper substrate and the lower substrate, and the power module work in process may be in a state before the upper substrate is bonded to the upper portion of the semiconductor device through the bonding member.

### BRIEF DESCRIPTION OF DRAWINGS

The above and other aspects, features, and advantages of the present disclosure will be more clearly understood from the detailed following description, taken in conjunction with the accompanying drawings.

FIG. 1 is a perspective view showing an example of a power module.

FIG. 2 is a cross-sectional view showing an example of a power module.

FIG. 3 illustrates an example of a probe device for testing electrical characteristics of a power module.

FIG. 4 illustrates an example of a method for testing a power module.

FIG. 5 schematically illustrates an example state in which a probe device and a power module are in contact in a test method of a power module.

FIG. 6 schematically illustrates an example state in which a probe device and a power module are in contact in a test method of a power module.

FIGS. 7A, 7B, and 7C illustrate a manufacturing process of a power module.

### DETAILED DESCRIPTION

Hereinafter, the present disclosure will be described in detail with reference to the accompanying drawings. In adding reference numerals to elements of each of the drawings, although the same elements are illustrated in other drawings, like reference numerals may refer to like elements. Since the present disclosure can make various changes and have various implementations, specific implementations are illustrated in the drawings and described in detail. However, this is not intended to limit the present disclosure to specific implementations, and should be understood to include all modifications, equivalents, and substitutes included in the spirit and scope of the present disclosure.

Hereinafter, one or more implementations of the present disclosure will be described with reference to the drawings.

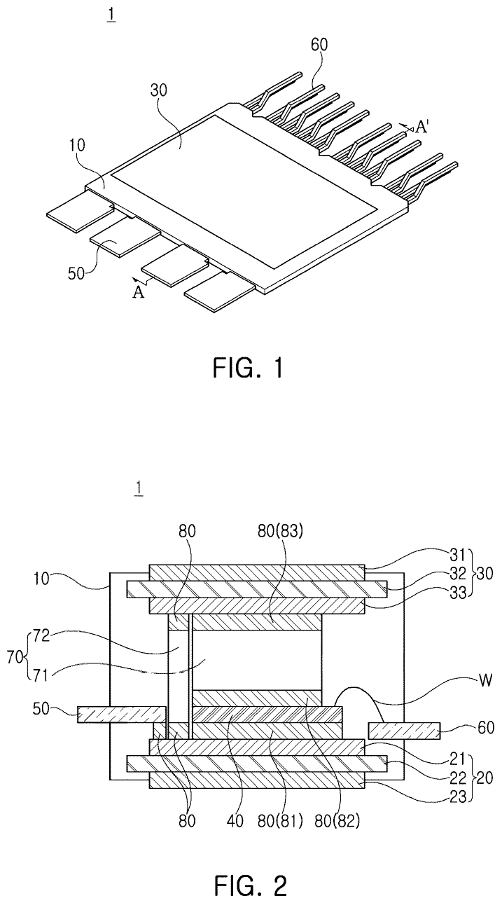

FIG. 1 is a perspective view of an example of a power module 1. FIG. 2 is a cross-sectional view of the power module 1.

FIG. 2 is a diagram schematically illustrating a cross section taken along line A-A′ of the power module 1 illustrated in FIG. 1.

In some implementations, referring to FIGS. 1 and 2, the power module 1 can include a housing 10, a lower substrate 20, an upper substrate 30, a semiconductor device 40, a power lead 50, a signal lead 60, a wire W, a spacer 70, and a bonding member 80.

The housing 10 can accommodate at least a portion of components constituting the power module 1 therein. For example, the housing 10 may surround components disposed between the lower substrate 20 and the upper substrate 30 so that at least a portion of the lower substrate 20, the upper substrate 30, the power lead 50, and the signal lead 60 are exposed externally, The housing 10 may be a molding portion formed of an insulating material that molds the components constituting the power module 1.

The lower substrate 20 may y include an insulating layer 22 and metal layers 21 and 23 disposed on both surfaces of the insulating layer 22. The metal layers 21 and 23 may include a first metal layer 21 bonded to an upper surface of the insulating layer 22 and a second metal layer 23 bonded to a lower surface of the insulating layer 22. The first metal layer 21 of the lower substrate 20 may be in electrical contact with a lower surface of the semiconductor device 40. At least a portion (e.g., a lower surface) of the second metal layer 23 of the lower substrate 20 may be located outside the housing 10 and exposed. In some examples, the second metal layer 23 of the lower substrate 20 may be in contact with a cooling channel for cooling the power module 1.

The upper substrate 30 may include an insulating layer 32 and metal layers 31 and 33 disposed on both surfaces of the insulating layer 32. The metal layers 31 and 33 may include a first metal layer 33 bonded to a lower surface of the insulating layer 32 and a second metal layer 31 bonded to an upper surface of the insulating layer 32. The first metal layer 33 of the upper substrate 30 may be in electrical contact with the upper surface of the semiconductor device 40 through a first spacer 71. At least a portion (e.g., upper surface) of the second metal layer 31 of the upper substrate 30 may be located outside the housing 10 and exposed. In some examples, the second metal layer 31 of the upper substrate 30 may be in contact with a cooling channel for cooling the power module 1.

The lower substrate 20 and the upper substrate 30 may be Double Bonded Copper (DBC) substrates. For example, the upper substrate 30 and the lower substrate 20 may have insulating layers 22 and 32 formed of a ceramic material and metal layers 21, 23, 31 and 33 formed of a copper material, but the present disclosure is not limited thereto.

The lower substrate 20 and the upper substrate 30 may be electrically connected through a spacer 70. For example, the first metal layer 21 of the lower substrate 20 and the first metal layer 33 of the upper substrate 30 may be electrically connected through a second spacer 72. Some regions of the first metal layer 21 of the lower substrate 20 are electrically connected to the lower surface of the semiconductor device 40 and some regions of the first metal layer 21 of the lower substrate 20 electrically connected to the first metal layer 33 through the second spacer 72 may be configured to be electrically insulated.

A semiconductor device (or a semiconductor chip) 40 may be disposed between the lower substrate 20 and the upper substrate 30. For example, the semiconductor device 40 may be bonded to the first metal layer 21 of the lower substrate 20 and located between the lower substrate 20 and the upper substrate 30. The semiconductor device 40 may be electrically connected to the upper substrate 30 and the lower substrate 20. For example, the semiconductor device 40 may have power terminals formed on upper and lower surfaces, respectively, through which current for power conversion is input and output, and the power terminal formed on the lower surface may be electrically connected to the lower substrate 20, and the power terminal formed on the upper surface may be electrically connected to the upper substrate 30. The semiconductor device 40 may be comprised of an insulated gate bipolar transistor (IGBT) and a diode, but the present disclosure is not limited thereto.

The lower surface of the semiconductor device 40 may be bonded to the first metal layer 21 of the lower substrate 20 through a lower bonding member 81. The upper surface of the semiconductor device 40 may be bonded to the first spacer 71 through an upper bonding member 82 (e.g., a first upper bonding member). For example, the semiconductor device 40 may be electrically connected to the first metal layer 33 of the upper substrate 30 through the first spacer 71. The semiconductor device 40 may be electrically connected to a signal lead 60 through a wire W.

The power lead 50 may be connected to the semiconductor device 40 and can transmit and receive high-voltage current. The power lead 50 may be electrically connected to the semiconductor device 40. The power lead 50 may be provided in plural. At least a portion of the power lead 50 may be electrically bonded to the first metal layer 21 of the lower substrate 20 through a bonding member 80. For example, the power lead 50 may be bonded to the upper surface of the first metal layer 21 of the lower substrate 20 along with the semiconductor device 40. A portion of the power lead 50 may be exposed to an outside of the housing 10 in order to transmit and receive power to and from the outside of the power module 1. The power lead 50 may extend from an inside of the housing 10 toward the outside of the housing 10 so that at least a portion is exposed to the outside of the housing 10.

The signal lead 60 can receive a control signal for controlling the semiconductor device 40 from the outside of the power module 1. There may be provided a plurality of signal leads 60. The signal lead 60 may extend from the inside of the housing 10 toward the outside of the housing 10 so that at least a portion is exposed to the outside of the housing 10. The signal lead 60 may be electrically connected to the semiconductor device 40 through a wire W.

The spacer 70 may include a first spacer 71 disposed between the upper substrate 30 and the semiconductor device 40 and a second spacer 72 disposed between the upper substrate 30 and the lower substrate 20.

The first spacer 71 may have an upper surface bonded to the first metal layer 33 of the upper substrate 30 and a lower surface bonded to the semiconductor device 40, to form an electrical connection between the upper substrate 30 and the semiconductor device 40. For example, the lower surface of the first spacer 71 may be electrically and physically bonded to the semiconductor device 40 (e.g., an upper surface of the semiconductor device 40) through a first upper bonding member 82, and the upper surface of the first spacer 71 may be electrically and physically bonded to the first metal layer 33 of the upper substrate 30 (e.g., a lower surface of the first metal layer 33) through a second upper bonding member 83.

The second spacer 72 may have an upper surface bonded to the first metal layer 33 of the upper substrate 30 and a lower surface bonded to the first metal layer 21 of the lower substrate 20, to form an electrical connection between the upper substrate 30 and the lower substrate 20. For example, the upper and lower surfaces of the second spacer 72 may be respectively connected to the first metal layer 33 of the upper substrate 30 (e.g., a lower surface of the first metal layer 33) and the first metal layer 21 of the lower substrate 20 (e.g., an upper surface of the first metal layer 21) through a bonding member 80.

The bonding member 80 may electrically and physically bond components disposed on both surfaces of the bonding member 80. For example, the components disposed on both surfaces of the bonding member 80 may be electrically connected through the bonding member 80 and simultaneously mechanically (or physically) coupled to each other. The bonding member 80 may include various materials capable of soldering and/or sintering. For example, the bonding member 80 may be referred to as a soldering member and/or a sintering member.

As illustrated in FIGS. 1 and 2, the power module 1 according to an implementation may be a double-sided cooling type (DSC) configured so that a semiconductor device 40 is disposed between an upper substrate 30 and a lower substrate 20. However, a structure of the power module 1 is not limited to the illustrated implementation, it may be modified in various manners within the scope of implementing a structure in which a semiconductor device 40 is disposed between the upper and lower substrates 20 and 30, and heat generated from the semiconductor device 40 is cooled using a cooler installed outside the two substrates.

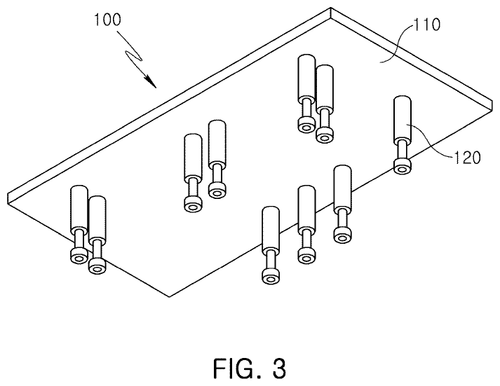

FIG. 3 illustrates a probe device 100 for testing electrical characteristics of the power module 1.

Referring to FIG. 3, the probe device 100 according to an implementation may be used to inspect and test the electrical characteristics of the power module 1 by contacting at least a portion of the power module 1. The probe device 100 can electrically connect and connect the power module 1 and a test device (or tester).

The probe device 100 according to an implementation may include a plate 110 and a plurality of contact pins 120 disposed on the plate 110.

The plate 110 may be equipped with a plurality of contact pins 120, and the plurality of contact pins 120 may be coupled to one surface of the plate 110. For example, the plate 110 may be referred to as a probe card.

The plurality of contact pins 120 may be coupled to the plate 110 as an electrical connector. The plurality of contact pins 120 may contact some components (e.g., semiconductor device 40) of the power module, the device under test 1. For example, the plurality of contact pins 120 may include a pogo pin or a spring-loaded pin.

The plurality of contact pins 120 may electrically connect a tester and the power module 1. The plurality of contact pins 120 may be coupled to the plate 110 and electrically connected to the tester. For example, the plurality of contact pins 120 may be electrically connected to the tester using a separate electric wire. However, a method by which the plurality of contact pins 120 are electrically connected to the tester is not limited to the above-described example.

According to various implementations, the plurality of contact pins 120 may be electrically connected to the tester through a plate 110. For example, the plate 110 may be comprised of a circuit board and be electrically connected to the tester, and as the plurality of contact pins 120 are electrically contacted and connected to the plate 110, the plurality of contact pins 120 may be electrically connected to the test through the plate 110.

The plurality of contact pins 120 may be detachably coupled to the plate 110. For example, the probe device 100 may be configured so that the number of the plurality of contact pins 120 and a position to which the plurality of contact pins 120 are coupled to the plate 110 are changed corresponding to the position and number of the semiconductor device 40 in a power module 1, a device under test. A plurality of coupling holes to which a plurality of contact pins 120 may be coupled may be formed in the plate 110, and may be coupled to a coupling hole that can be in contact with the semiconductor device 40 among the plurality of coupling holes corresponding to the position and/or number of the semiconductor device 40. For example, in the process of testing the power module 1 using the probe device 100, the number and/or position of the plurality of contact pins 120 may be appropriately adjusted according to the number and/or position of the semiconductor device 40.

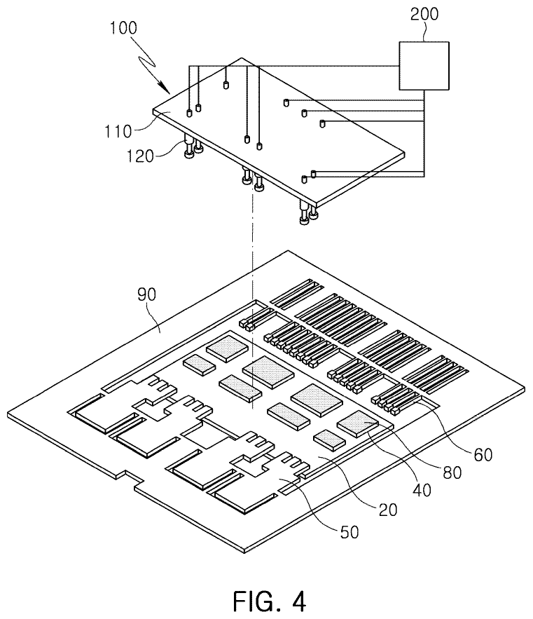

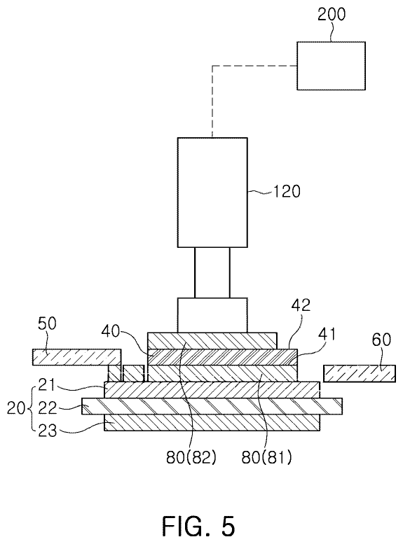

FIG. 4 illustrates a test method of the power module 1. FIG. 5 illustrates a state in which the probe device 100 and the power module 1 are in contact in the test method of the power module 1.

Referring to FIGS. 4 and 5, the method of testing electrical characteristics of the power module 1 according to an implementation may be performed in an intermediate process before the power module 1 illustrated in FIGS. 1 and 2 is completed. In describing FIGS. 4 and 5, FIGS, 1 and 2 are referred to together.

Hereinafter, the test method of the power module 1 according to an implementation is described as a method of testing DC characteristics of the semiconductor device 40 of the power module 1, but electrical characteristics and items to be evaluated through the test method of the present disclosure is not limited to the DC characteristics.

A DC test is a test in which DC characteristics such as open/short, input current, output voltage, and power current by applying a preset voltage and/or current is applied to the power module 1, to determine whether the semiconductor device 40 in the power module 1 operates properly.

In the test method of the power module 1 according to an implementation, a power module 1, a device under test (DUT), may be in a state of a work in process before the double-sided cooling power module 1 of FIGS. 1 and 2 is completed.

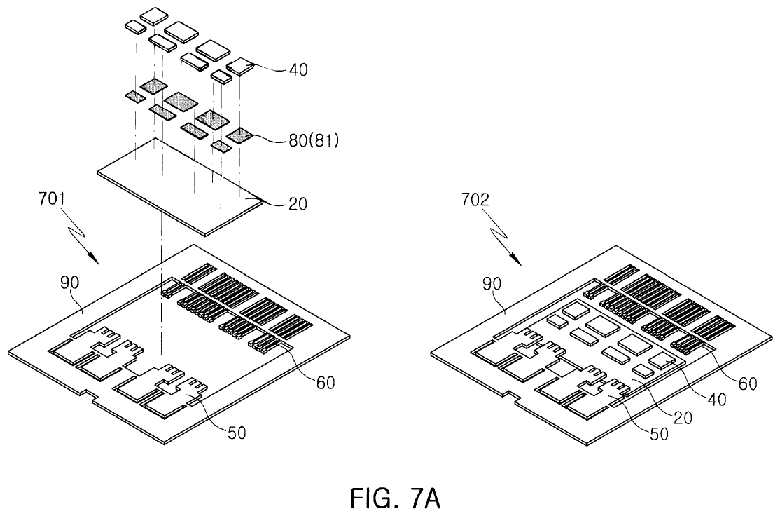

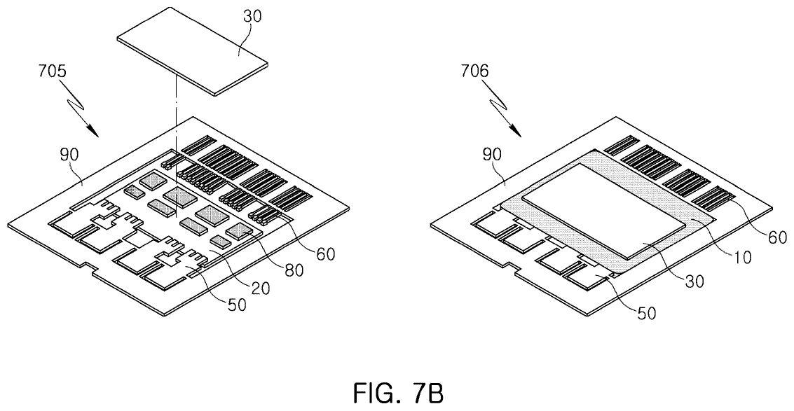

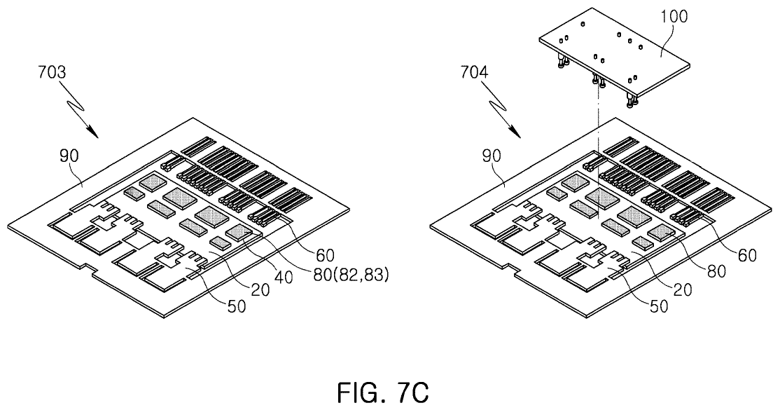

The power module, the device under test 1 may be a power module work in process (e.g., power module work in process illustrated in 703 in FIG. 7B) in which at least one semiconductor device 40 is bonded to a lower substrate 20, and in a state in which a bonding member 80 for bonding an upper substrate (e.g., upper substrate 30 in FIGS. 1 and 2) and/or a spacer (e.g., spacer 70 in FIG. 2) is disposed on an upper portion of the semiconductor device 40.

For example, in the power module, the device under test (DUT) 1, the lower substrate 20 and the semiconductor device 40 may be bonded (e.g., primary soldering and/or sintering) through a lower bonding member 81 disposed between the lower surface 41 of the semiconductor device 40 and the lower substrate 20, and the upper bonding member (e.g., first upper bonding member) 82 may be disposed on an upper surface 42 of the semiconductor device 40 before the upper substrate 30 (or, the upper substrate 30 and the first spacer 71) is bonded to the semiconductor device 40 (e.g., secondary soldering and/or sintering). Here, the upper bonding member 82 may be bonded to the upper surface 42 of the semiconductor device 40 as it is melted and solidified together with the lower bonding member 81 in the process of bonding the semiconductor device 40 and the lower substrate 20, so that the upper bonding member 82 may be bonded to the upper surface 42 of the semiconductor device 40.

The semiconductor devices 40 bonded to the lower substrate 20 may be provided in plural. In addition, the number and/or position of the semiconductor devices 40 are not limited to the illustrated implementation.

The test method of the power module 1 may include operations of preparing a power module, a device under test 1, contacting the probe device 100 (e.g., a plurality of contact pins 120) with the upper bonding member 82, and applying an electrical signal for testing. Here, the operation of preparing the power module, the device under test 1, may refer to an operation of manufacturing a work in process with the upper bonding member 82 disposed on an upper portion of the semiconductor device 40 bonded to the lower substrate 20. According to various implementations, at least some operations of the method for testing the power module 1 may be included in a method for manufacturing the power module 1 (e.g., see FIGS. 7A, 7B and 7C).

In the test method of the power module 1, the probe device 100 may be configured so that the plurality of contact pins 120 contact an upper bonding member 82 disposed on the upper surface 42 of the semiconductor 40 above the power module, the device under test 1. The plurality of contact pins 120 may be electrically connected to the semiconductor device 40 by contacting the upper bonding member 82 having electrical conductivity. For example, the plurality of contact pins 120 may transmit an electrical signal received from the DC tester 200 to the semiconductor device 40 through the upper bonding member 82.

The probe device 100 may be electrically connected to a DC tester 200. For example, the probe device 100 may have a plurality of contact pins 120 disposed from a lower surface through an upper surface of the plate 110, and a portion of the plurality of contact pins 120 penetrating through the upper surface of the plate 110 may be electrically connected to the DC tester 200. The plurality of contact pins 120 may be electrically connected to the DC tester 200 through conductive wires. However, an electrical connection method between the plurality of contact pins 120 and the DC tester 200 is not limited to the illustrated implementation.

The DC tester 200 can apply and sense an electrical signal for a DC test to the semiconductor device 40 through the plurality of contact pins 120. For example, after contacting the plurality of contact pins 120 of the probe device 100 with the upper bonding member 82 disposed on the upper surface 42 of the semiconductor device 40, current and/or voltage application conditions are set for each circuit for each terminal in the DC tester 200, and the set current and/or voltage is applied for testing. Since the DC test process for semiconductors is a well-known technology in the relevant technical field, detailed descriptions of more specific methods will be omitted.

According to the test method of the present disclosure, the electrical characteristics are tested by contacting the probe device 100 with the bonding member 80 disposed on the upper portion of the semiconductor element 40 in an intermediate process before the power module 1 is completed, defects can be detected in an initial stage of the manufacturing process without damage or destruction of the semiconductor device 40.

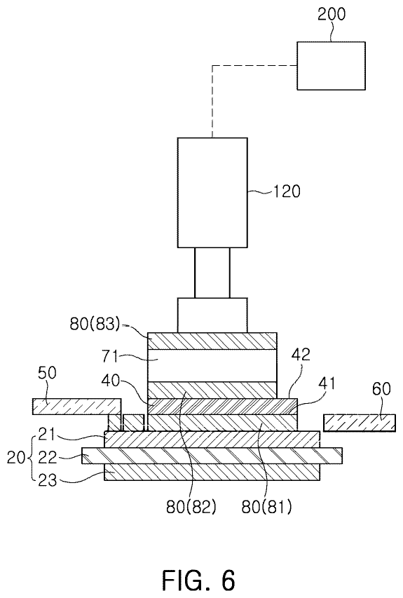

FIG. 6 schematically illustrates a state in which a probe device 100 and a power module 1 are in contact in a test method of the power module 1.

Referring to FIG. 6, unlike the implementation illustrated in FIG. 5, in the test method of the power module 1, in a state in which a first spacer 71 is bonded to an upper surface 42 of a semiconductor device 40, the probe device 100 may be configured to contact an upper bonding member 83 (e.g., a second bonding member) disposed on an upper portion of the first spacer 71.

In the implementation illustrated in FIG. 6, in the power module, the device under test 1, the lower substrate 20, the semiconductor device 40, and the first spacer 71 are stacked and bonded (e.g., primary soldering and/or sintering) through a lower bonding member 81 disposed between the lower surface 41 of the semiconductor device 40 and the lower substrate 20, and a first upper bonding member 82 dispose between the upper surface 42 of the semiconductor device 40 and the first spacer 71, and the second upper bonding member 82 may be disposed on the upper surface 42 of the first spacer 71 before the upper substrate 30 is bonded to the first spacer 71 (e.g., secondary soldering and/or sintering). Here, in a process of bonding the semiconductor device 40, the lower substrate 20, and the first spacer 71, the second upper bonding member 82 may be bonded to the upper surface of the first spacer 71 as it is melted and solidified together with the lower bonding member 81 and the first upper bonding member 82.

According to the implementation illustrated in FIG. 6, the plurality of contact pins 120 may be configured to contact the second upper bonding member 83 disposed on the upper surface of the first spacer 71. The plurality of contact pins 120 may be electrically connected to the semiconductor device 40 through the first spacer 71 and the first upper bonding member 82 by contacting the second upper bonding member 83 having electrical conductivity. For example, the plurality of contact pins 120 may transmit an electrical signal received from the DC tester 200 to the semiconductor device 40 through the second upper bonding member 83, the first spacer 71, and the first upper bonding member 82.

FIGS. 7A, 7B, and 7C illustrate a manufacturing method of the power module 1.

Referring to FIGS. 7A, 7B, and 7C, a manufacturing method of the power module 1 may include the test method (or the test process) of the power module 1 described with reference to FIGS. 4 to 6.

The manufacturing method of the power module 1 may include an operation of mounting a component on a lead frame (701), an operation of bonding a semiconductor device to a lower substrate (702), an operation of disposing a bonding member on an upper portion of the semiconductor device (703), an operation of testing electrical characteristics by contacting a probe device with a bonding member on an upper portion of the semiconductor device (704), an operation of bonding an upper substrate (705), and a molding step (706).

The operation of bonding the semiconductor device to the lower substrate 702 and the operation of disposing the bonding member on an upper portion of the semiconductor device 703 may be performed simultaneously. For example, in a state in which a lower bonding member 81 is disposed between the lower substrate 20 and the semiconductor device 40, and an upper bonding member 80 is disposed on an upper portion of the semiconductor device 40, by applying heat to melt and solidify the bonding member 80, the semiconductor device 40 may be bonded to the lower substrate 20 and the bonding member 80 can be disposed on the upper portion of the semiconductor device 40. However, this is an example, and the manufacturing method is not limited to the above-described contents.

In the operation of testing the electrical characteristics by contacting the probe device with the bonding member on the upper portion of the semiconductor device 704, the bonding member 80 disposed on the upper portion of the semiconductor device 40 may be a first upper bonding member 82 or a second upper bonding member 83, which may be determined according to various implementations of the manufacturing method.

For example, depending on the manufacturing method, in the operation of disposing a bonding member on the upper portion of the semiconductor device, only the first upper bonding member 82 may be disposed on the upper portion of the semiconductor device 40, and in this case, the probe device 100 may be in contact with the first upper bonding member 82. In addition, in this case, the operation of bonding the upper substrate 705 is performed in such a manner that the upper substrate 30 in a state in which the first spacer 71 is bonded is bonded to the semiconductor device 40.

For another example, depending on the manufacturing method, in the operation of disposing a bonding member on the upper portion of the semiconductor device 703, the first upper bonding member 82, the first spacer 71, and the second upper bonding member 83 may be sequentially stacked and disposed on the upper portion of the semiconductor device 40, and in this case, the probe device 100 may contact the second upper bonding member 83. In addition, in this case, the operation of bonding the upper substrate is performed in such a manner that the upper substrate 30 is bonded to the first spacer 71 in a state in which the upper substrate 30 is bonded to the upper portion of the semiconductor device 40.

In the molding step 706, epoxy molding compound (EMC) may be melted and then hardened to form a housing (e.g., housing 10 in FIG. 1) to surround and protect the semiconductor device 40. For example, the molding step 706 may be referred to as an encapsulation process.

In some examples, in the manufacturing method of the power module 1 according to an implementation, a process of connecting the signal lead 60 and the semiconductor device 40 with a wire W may be performed before the operation of bonding the upper substrate 705.

In some examples, in the manufacturing method of the power module 1, a trimming process for removing dambar which maintains a shape of a lead frame 90 to separate the power lead 50 and the signal lead 60 from the lead frame 90 may be performed after the molding step 706. For example, as the trimming process is performed in step 706 of FIG. 7C, it may have the form of the power module 1 illustrated in FIG. 1.

Meanwhile, the manufacturing method illustrated in FIGS. 7A, 7B, and 7C is an example, and the manufacturing method of the power module 1 according to an implementation is not limited to the illustrated implementation, and according to various implementations, some operations may be omitted and/or added, or some operations may be merged and/or separated.

As set forth above, material costs and processing costs may be reduced by detecting defects in a semiconductor device in advance before a power module is completed, and a cause of the detects in the semiconductor device may be easily analyzed.

In addition, for a double-sided cooling power module, by contacting a bonding member disposed on an upper surface of the semiconductor device bonded to the lower substrate before the upper substrate is bonded and testing the same, testing may be performed without damaging the semiconductor device.

The aforementioned description merely illustrates the technical concept of the present disclosure, and a person skilled in the art to which the present disclosure pertains may make various modifications and modifications without departing from the essential characteristics of the present disclosure.

In some implementations, some components may be deleted, and the components of each implementation may be combined with each other.

Therefore, the example implementations disclosed in this specification and drawings are not intended to limit but to explain the technical concept of the present disclosure, and the scope of the technical idea of the present disclosure is not limited by these example implementations. The scope of protection of the present disclosure should be interpreted by the following claims, and all technical ideas within the scope equivalent thereto should be interpreted as being included in the scope of the present disclosure.

What is claimed is:

1. A manufacturing method of a power module, comprising:
bonding a semiconductor device to a lower substrate;
disposing an upper bonding member on an upper portion of the semiconductor device;
contacting a probe device with the upper bonding member;
electrically connecting the probe device to a tester;
detecting electrical characteristics of the semiconductor device using the tester; and
bonding an upper substrate to the semiconductor device with the upper bonding member.

2. The manufacturing method of claim 1, further comprising:
performing a molding operation after bonding the upper substrate to the semiconductor device.

3. The manufacturing method of claim 1, further comprising:
bonding a signal lead to the semiconductor device,
wherein bonding the signal lead to the semiconductor device is performed between detecting the electrical characteristics of the semiconductor device and bonding the upper substrate.

4. The manufacturing method of claim 1, wherein bonding the semiconductor device to the lower substrate comprises:
disposing a lower bonding member between a lower surface of the semiconductor device and the lower substrate; and
boding the semiconductor device to the lower substrate with the lower bonding member.

5. The manufacturing method of claim 4, wherein the lower bonding member and the upper bonding member comprise a material having an electrical conductivity.

6. The manufacturing method of claim 5, wherein the lower bonding member and the upper bonding member comprise a material for at least one of soldering or sintering.

7. The manufacturing method of claim 1, wherein the probe device comprises a contact pin that is electrically connected to the tester and configured to contact the upper bonding member, and
wherein contacting the probe device with the upper bonding member comprises electrically connecting the contact pin to the semiconductor device through the upper bonding member.

8. The manufacturing method of claim 7, wherein the probe device further comprises a plate to which a plurality of contact pins are detachably coupled, the contact pin being one of the plurality of contact pins, and
wherein bonding the semiconductor device to the lower substrate comprises bonding a plurality of semiconductor devices to the lower substrate, the semiconductor device being one of the plurality of semiconductor devices.

9. The manufacturing method of claim 8, wherein contacting the probe device with the upper bonding member comprises:
adjusting a number and a position of the plurality of contact pins to match a number and a position of the plurality of semiconductor devices, respectively.

10. The manufacturing method of claim 1, wherein disposing the upper bonding member on the upper portion of the semiconductor device comprises disposing a first upper bonding member on an upper surface of the semiconductor device, and
wherein contacting the probe device with the upper bonding member comprises contacting the probe device with the first upper bonding member.

11. The manufacturing method of claim 1, wherein disposing the upper bonding member on the upper portion of the semiconductor device comprises:
disposing a first upper bonding member on an upper surface of the semiconductor device;
disposing a spacer on an upper portion of the first upper bonding member; and
disposing a second upper bonding member on an upper portion of the spacer, and
wherein contacting the probe device with the upper bonding member comprises contacting the probe device with the second upper bonding member.

12. The manufacturing method of claim 11, wherein contacting the probe device with the second upper bonding member comprises electrically connecting the probe device to the semiconductor device through the second upper bonding member, the spacer, and the first upper bonding member.

13. The manufacturing method of claim 1, wherein detecting the electrical characteristics of the semiconductor device comprises:
applying, by the tester, an electrical signal to the semiconductor device through the probe device.

14. A test method of a power module, comprising:
preparing the power module that is a device under test for testing electrical characteristics thereof;
contacting a probe device with the power module;
electrically connecting the probe device with a tester; and
applying, by the tester, an electrical signal to the power module,
wherein preparing the power module comprises:
providing the power module in a work-in-process state in which a semiconductor device is bonded to a lower substrate, and a bonding member is disposed on an upper portion of the semiconductor device, and
wherein contacting the probe device with the power module comprises contacting the probe device with the bonding member disposed on the upper portion of the semiconductor device of the power module in the work-in-process state.

15. The test method of claim 14, wherein the probe device comprises one or more contact pins, wherein a number of the one or more contact pins corresponds to a number of one or more semiconductor devices of the power module, the one or more semiconductor devices including the semiconductor device, and
wherein contacting the probe device with the power module comprises contacting the one or more contact pins with the bonding member.

16. The test method of claim 14, wherein the bonding member comprises a material having an electrical conductivity.

17. The test method of claim 14, wherein a finished product of the power module includes the semiconductor device bonded between an upper substrate and the lower substrate, and
wherein the work-in-process state of the power module is before the upper substrate is bonded to an upper portion of the semiconductor device through the bonding member.
